(19) United States
(12) Patent Application Publication
(10) Pub. No.: US 2002/0041249 A1
(43) Pub. Date: Apr. 11, 2002

(54) Comparator and converter using the same

(75) Inventor: Masayuki Ueno, Chiba-shi (JP)

Correspondence Address: OLIFF & BERRIDGE, PLC, P.O. BOX 19928, ALEXANDRIA, VA, 22320, US

(73) Assignee: KAWASAKI MICROELECTRONICS, INC., Chiba-shi (JP)

(21) Appl. No.: 09/964,331

(22) Filed: Sep. 28, 2001

(30) Foreign Application Priority Data
Oct. 6, 2000 (JP) 2000-307238

(51) Int. Cl. H03M 1/36

(52) U.S. Cl. 341/159

(57) ABSTRACT

A compact comparator is capable of high-speed operation and a high-speed A/D converter formed using this comparator. In this comparator, the input and output terminals of a first inverter are short-circuited, and the output become equivalent to the logical threshold voltage of the first inverter. The output of an operational amplifier is adjusted so that the logical threshold voltage of the first inverter equals to a reference voltage, and a current corresponding to the output of the operational amplifier is supplied to the first inverter via a first transistor. In response to this current, the logical threshold voltage of the first inverter is adjusted to become equal to the reference voltage. Because the first transistor and a second transistor constitute a current mirror circuit, the logical threshold voltage of the second transistor is also adjusted to become equal to the reference voltage.

### BACKGROUND OF THE INVENTION

1. Field of Invention

The present invention relates to a compact comparator capable of high-speed operation, and to a high-speed A/D converter (analog-to-digital converter) formed using this compact comparator.

2. Description of Related Art

FIG. 5 shows a circuit diagram of an example of a conventional comparator.

The comparator 42 shown in FIG. 5 is a chopper-type comparator including an N-type MOS transistor (hereinafter abbreviated as “NMOS”) 44, an NMOS 46, a capacitor (C) 48, an NMOS 50, an inverter 52 and an inverter 54. The comparator 42 compares the voltage of an analog input signal Vin with a reference voltage Vref, and outputs the comparison result.

The NMOS 44 is connected between the analog input signal Vin and one terminal of the capacitor 48. The NMOS 46 is connected between the reference voltage Vref and the same terminal connected to NMOS 44 of the capacitor 48. The capacitor 48 and the inverters 52 and 54 are connected in series in this order, and the NMOS 50 is connected between an input and an output of the inverter 52. A clock signal φ is input to each gate of the NMOSs 44 and 50. An inverted clock signal \overline{φ} that is an inverse signal of the clock signal φ is input to a gate of the NMOS 46.

As shown in the timing chart in FIG. 6, in the chopper-type comparator 42, the analog input signal Vin is sampled in the capacitor 48 during the period S when the clock signal φ is at a high level (the inverted clock signal \overline{φ} is at a low level). On the other hand, the sampled analog input signal Vin is compared with the reference voltage Vref during the period C when the clock signal φ is at a low level (the inverted clock signal \overline{φ} is at a high level).

In this chopper-type comparator 42, the NMOS 44 and the NMOS 50 are turned on, and the NMOS 46 is turned off, during the sampling period when the clock signal φ is at a high level. At this time, since the input and output terminals of the inverter 52 are short-circuited via the NMOS 50, the input and output voltage becomes the logical threshold voltage Vth of the inverter 52. The voltage of the analog input signal Vin is applied to the capacitor 48, and the voltage charged in the capacitor 48 becomes (Vin−Vth).

Next, the NMOS 44 and the NMOS 50 are turned off, and the NMOS 46 is turned on, during the comparison period when the clock signal φ is at a low level. At this time, the reference voltage Vref is applied to one terminal of the capacitor 48. The voltage at the other terminal of the capacitor 48, that is, the voltage at the input terminal of the inverter 52, becomes (Vin−Vref+Vth), in response to the applied voltage variation (Vin−Vref) between the voltage of the analog input signal Vin and the reference voltage Vref.

This voltage at the other terminal of the capacitor 48 is amplified by the inverter 52, and is output from the inverter 54 as a comparison result. Specifically, when the voltage of the analog input signal Vin is higher than the reference voltage Vref, i.e., Vref<Vin, the voltage at the other terminal of the capacitor 48 becomes lower than the logical threshold voltage Vth of the inverter 52. This voltage is inverted by the inverter 52, so that the comparison result output from the inverter 54 becomes “0” (low level). Conversely, when the voltage of the analog input signal Vin is lower than the reference voltage Vref, i.e., Vref>Vin, the comparison result becomes “1” (high level).

Meanwhile, because the chopper-type comparator 42 requires a sampling period and a comparison period to control the NMOSs 44, 46, and 50 by a clock signal φ and an inverted clock signal \overline{φ}, high-speed operation of the comparator becomes severely restricted. Accordingly, the chopper-type comparator 42 cannot be used for an A/D converter that is required for high speed operation. In addition, the chopper-type comparator 42 requires a capacitor element that occupies a large layout area as the capacitor 48, for example, a capacitor element formed of two-layer polysilicon or the like, resulting in increased production costs.

In order to solve these problems, Japanese Patent No. 2854204, to the same assignee as the present application, proposes a compact comparator capable of realizing high-speed operation by controlling the logic threshold voltage so as to become equal to the reference voltage.

FIG. 7 is a circuit diagram of the comparator disclosed in the above-mentioned Japanese Patent No. 2854204.

A comparator 56 shown in FIG. 7 includes an operational amplifier 58 and inverters 60 and 62.

The input and output terminals of the inverter 60 are short-circuited, and the output thereof is also input to the negative terminal of the operational amplifier 58. A reference voltage Vref is input to the positive terminal of the operational amplifier 58, and the output of amplifier 58 is supplied to the power supply terminals of the inverters 60 and 62. The ground terminals of the inverters 60 and 62 are connected to the ground. An analog input signal Vin is input to the inverter 62, and the result of the comparison between the analog input signal Vin and the reference voltage Vref is output from the inverter 62.

The output of the operational amplifier 58 is controlled so that the level of the reference voltage Vref input to the positive terminal equals to the voltage level input to the negative terminal, that is, the short-circuited level of the input and output terminals of the inverter 60. Because the input and output terminals of the inverter 60 are thus short-circuited, the output of the inverter 60 is equivalent to the logical threshold voltage of the inverter 60. The output of the operational amplifier 58, therefore, is supplied to the inverters 60 and 62 as power so that the logical threshold voltage of the inverter 60 equals to the reference voltage Vref. In this manner, the logical threshold voltage of the inverters 60 and 62 is adjusted to become equal to the reference voltage Vref.

The analog input signal Vin is inverted by the inverter 62, and output as a comparison result. When the voltage of the analog input signal Vin is lower than the reference voltage Vref, i.e., Vin<Vref, the analog input signal Vin is inverted by the inverter 62, and the output of the inverter 62 becomes “1” (high level). Conversely, when the voltage of the analog input signal Vin is higher than the reference voltage Vref, i.e., Vin>Vref, the output of the inverter 62 becomes “0” (low level).

Since this comparator 56 requires neither the clock signal φ nor the capacitor 48, which is required in the case of the chopper-type comparator 42 shown in FIG. 5, the comparator 56 has an advantage of being compact and capable of high-speed operation.

However, in the comparator 56, because power is directly supplied to the inverters 60 and 62 from the output of the operational amplifier 58, the output of the operational amplifier 58 fluctuates whenever the output of the inverter 62 is inverted, thus, it is wasting time trying to stabilize the behavior of the operational amplifier 58. In addition, because the operational amplifier 58 is adapted to supply power to the inverters, it is necessary to increase the size of the operational amplifier 58 in order to operate it at high speed. It is, therefore, inevitable that the layout area of the operational amplifier 58 increases in accordance with increasing speed.

Next, a conventional A/D converter will be described.

FIG. 8 is a schematic diagram showing the construction of an example of a conventional A/D converter.

An A/D converter 64 shown in FIG. 8 comprises two comparators 66 and an encoder 68. The voltage of an analog input signal Vin is input to the positive terminal of each of the two comparators 66, and corresponding reference voltages Vref1 and Vref2 are input to the negative terminals of the two comparators 66, respectively. The output signals of the comparators 66 are input to the encoder 68, and a digital output signal Dout is output from the encoder 68.

In the A/D converter 64, the voltage of the analog input signal Vin is compared with the two reference voltages Vref1 and Vref2 in parallel by the comparators 66. The comparison results are encoded by the encoder 68, and converted into the digital output signal Dout corresponding to the analog input signal Vin.

The A/D converter 64 is representative of a conventional A/D converter formed using the comparators 66 that are capable of high-speed operation.

However, in the conventional A/D converter 64, if a latch is used as an example of a comparator capable of high-speed operation, the converter 64 will cause noise, or advancement in the operating speed and accuracy will also be limited. Even if a differential-type comparator is used instead, this will also place a constraint on high-speed operation.

### SUMMARY OF THE INVENTION

It is an object of the present invention to solve the problems caused by the above-described conventional art, and to provide a compact comparator capable of high-speed operation, and to provide a high-speed A/D converter using this compact comparator.

In order to achieve the above-described object, the present invention provides a comparator including a dummy section and a comparison section. The dummy section includes a first inverter, an operational amplifier and a first transistor. The input terminal and the output terminal of the first inverter are short-circuited. The output voltage of the operational amplifier is controlled so that the output voltage of the first inverter become equal to a reference voltage. The first transistor is connected between a power supply or the ground and the power supply terminal or the ground terminal, respectively, of the first inverter. The output of the operational amplifier is input to the gate of the first transistor. The comparison section includes a second inverter and a second transistor. An analog input signal is input to the second inverter. The second transistor is connected between the power supply or the ground and the power supply terminal or the ground terminal, respectively, of the second inverter. The output of the operational amplifier is input to the gate of the second transistor.

It is preferable that, in the first and second inverters, the ground terminals or power supply terminals to which the first and second transistors have not been connected, is connected to the ground or the power supply, respectively.

It is preferable that the first inverter and the first transistor in the dummy section are formed to be similar in shapes to the second inverter and the second transistor in the comparison section, respectively.

Preferably, the comparison section includes a plurality of stages, and each stage includes a pair of the second inverter and the second transistor. Also, preferably, the analog input signal is input to the second inverter at the first stage, and the output of the second inverter at the previous stage is input to the second inverter at the next stage.

The present invention further provides an A/D converter formed using a comparator in accordance with the present invention.

Preferably, the above-mentioned comparator includes at least one N-type comparator and at least one P-type comparator. It is further preferable that, one side at which the potential is higher than the potential substantially at the midpoint between the power supply and the ground be formed using the N-type comparator, while another side at which the potential is lower than the potential substantially at the midpoint between the power supply and the ground be formed using the P-type comparator.

The above and other objects, features, and advantages of the present invention can be better understood from the following detailed description of the preferred embodiments of the invention in conjunction with the accompanying drawings.

### BRIEF DESCRIPTION OF THE DRAWINGS

FIG. 1 is a circuit diagram of a comparator in accordance with an embodiment of the present invention;

FIGS. 2A and 2B are diagrams each showing the input/output characteristic of an inverter in accordance with an embodiment of the present invention;

FIG. 3 is a circuit diagram of a comparator in accordance with another embodiment of the present invention;

FIG. 4 is a schematic diagram showing the construction of an A/D converter in accordance with an embodiment of the present invention;

FIG. 5 is a circuit diagram of an example of a conventional comparator;

FIG. 6 is a timing chart illustrating an example of the actions of a clock signal φ and inverted clock signal \overline{φ} of the comparator shown in FIG. 5;

FIG. 7 is a circuit diagram of another example of a conventional comparator; and

FIG. 8 is a schematic diagram showing the construction of an example of a conventional A/D converter.

### DESCRIPTION OF THE PREFERRED EMBODIMENTS

First, a preferred embodiment of a compact comparator in accordance with the present invention is described in detail.

FIG. 1 is a circuit diagram of a comparator 10 in accordance with an embodiment of the present invention.

The comparator 10 shown in FIG. 1 is a P-type comparator that compares the voltage of an analog input signal Vin with a reference voltage Vref, and that outputs the comparison result Vout. The comparator 10 includes a dummy section 12 and a comparison section 14.

The dummy section 12 includes an inverter 16, an operational amplifier 18 and a P-type MOS transistor (hereinafter abbreviated as a “PMOS”) 20.

The input and output terminals of the inverter 16 are short-circuited, and the output of the inverter 16 is input to the positive terminal of the operational amplifier 18. The reference voltage Vref is input to the negative terminal of the operational amplifier 18, and the output of the operational amplifier 18 is connected to the gate of the PMOS 20. The PMOS 20 is connected between a power supply and the power supply terminal of the inverter 16, the ground terminal of the inverter 16 is connected to the ground.

The comparison section 14 includes two stages, and each stage includes a pair of an inverter 22 and a PMOS 24.

At each stage in the comparison section 14, the PMOS 24 is connected between the power supply and the power supply terminal of the inverter 22, and the output of the operational amplifier 18 is input to the gate of the PMOS 24. The ground terminals of the inverters 22 are connected to the ground. An analog input signal Vin is input to the first-stage inverter 22, and the output thereof is input to the next-stage inverter 22. The comparison result Vout is output from the next-stage inverter 22.

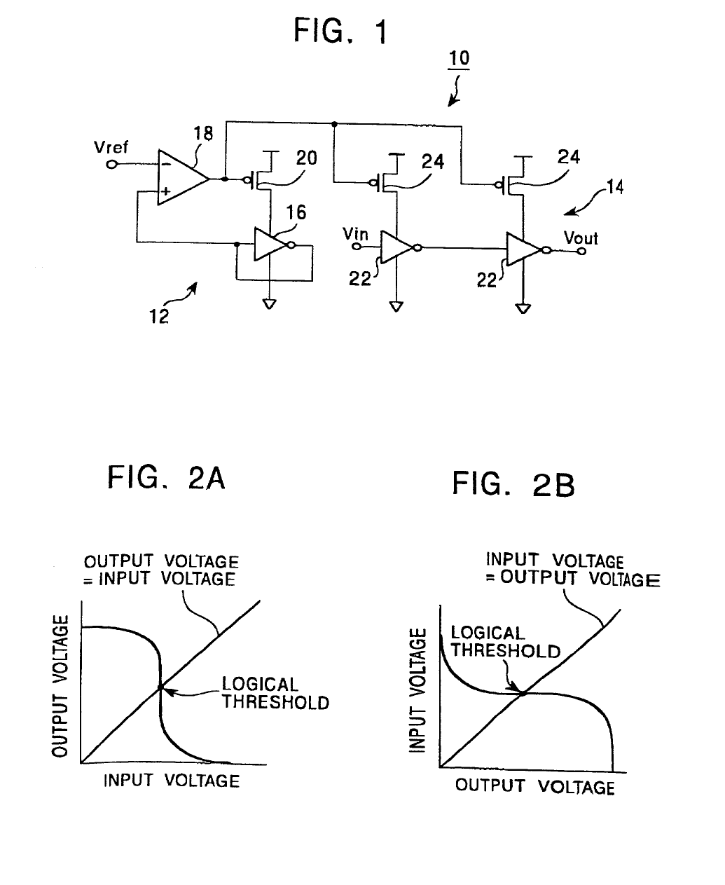

In the comparator 10, the input and output terminals of the inverter 16 in the dummy section 12 are short-circuited. In this case, the behavior of the inverter 16 is stabilized at the point where the input and output voltages of the inverter 16 are equal to each other, that is, at the point of the logical threshold voltage of the inverter 16, as illustrated in the input/output characteristic diagrams in FIGS. 2A and 2B. In other words, the output of the inverter 16 is equivalent to the logical threshold voltage of the inverter 16.

The output of the inverter 16 is input to the operational amplifier 18. The gate voltage of the PMOS 20, i.e., the output voltage of the operational amplifier 18 is controlled so that the output of the inverter 16, i.e., the logical threshold voltage of the inverter 16 equals to the reference voltage Vref. A current corresponding to the output voltage of the operational amplifier 18 is supplied to the inverter 16 via the PMOS 20, and the logical threshold voltage of the inverter 16 is adjusted to become equal to the reference voltage Vref.

The PMOS 20 in the dummy section 12 and the PMOS 24 at each stage in the comparison section 14 constitute a current mirror circuit. At each stage in the comparison section 14, a current corresponding to the output voltage of the operational amplifier 18 is supplied to the inverter 22 via the PMOS 24, and the logical threshold voltage of the inverter 22 is also adjusted to become equal to the reference voltage Vref, as in the case of the inverter 16 in the dummy section.

In such a situation, at the first stage in the comparison section 14, when the voltage of the analog input signal Vin is higher than the reference voltage Vref, the analog input signal Vin is inverted by the inverter 22, so that the output of the inverter 22 becomes a low level. Conversely, when the voltage of the analog input signal voltage Vin is lower than the reference voltage Vref, the output of the inverter 22 becomes a high level. The output of the first-stage inverter 22 is inverted by the next-stage inverter 22, and is output as the comparison result Vout.

In the comparator 10 in accordance with the present invention, the output of the operational amplifier 18 is not directly input to the power supply terminals of the inverters 16 and 22, but is input to the gates of the PMOSs 20 and 24. Therefore, a current corresponding to the output voltage of the operational amplifier 18 is supplied to the inverters 16 and 22 via the PMOSs 20 and 24. In this case, since there is no output current (DC component) as a power supply from the operational amplifier 18 to the inverters 16 and 22, it is possible to operate the comparator 10 at high speed, even if the operational amplifier 18 is reduced in size.

In order to operate the comparator 10 at high speed, it is necessary to increase the sizes of the inverters 22 and the PMOSs 24 in the comparison section 14. It is preferable that the ratio of the sizes of the inverter 16 and PMOS 20 in the dummy section 12 with respect to the sizes of the inverters 22 and the PMOSs 24 in the comparison section 14 be 1:1, respectively. Alternatively, however, by reducing the size of the dummy section so that the above-described size-ratio becomes 1:n (n>1) while keeping the shape thereof similar, the layout area of the dummy section 12 can still be reduced, resulting in a decreased power consumption.

In this embodiment, the comparison section 14 is arranged to include two stages and to output a comparison result after waveform shaping. In such a manner, it is preferable that the comparison section 14 includes at least two stages, and that it outputs the comparison result upon waveform shaping. It is, however, essential that the comparison section 14 has at least one stage. When the comparison section 14 has at least two stages, the sizes of the inverters 22 at all stages and the PMOSs 24 at all stages may be the same. Furthermore, the sizes of the inverters 22 and the PMOSs 24 may be changed in a manner such as to gradually increase from the first stage on.

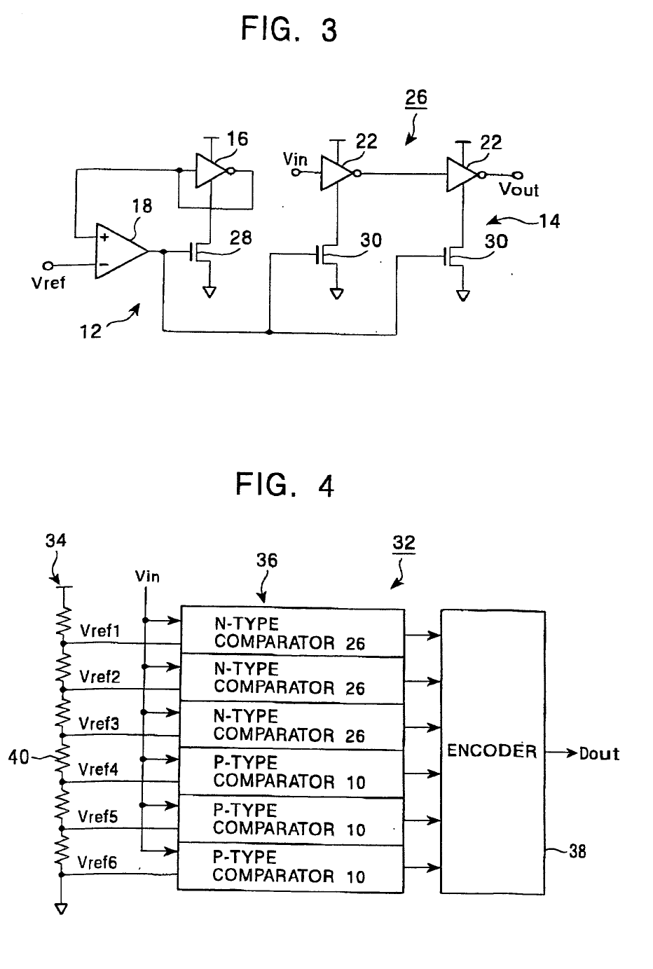

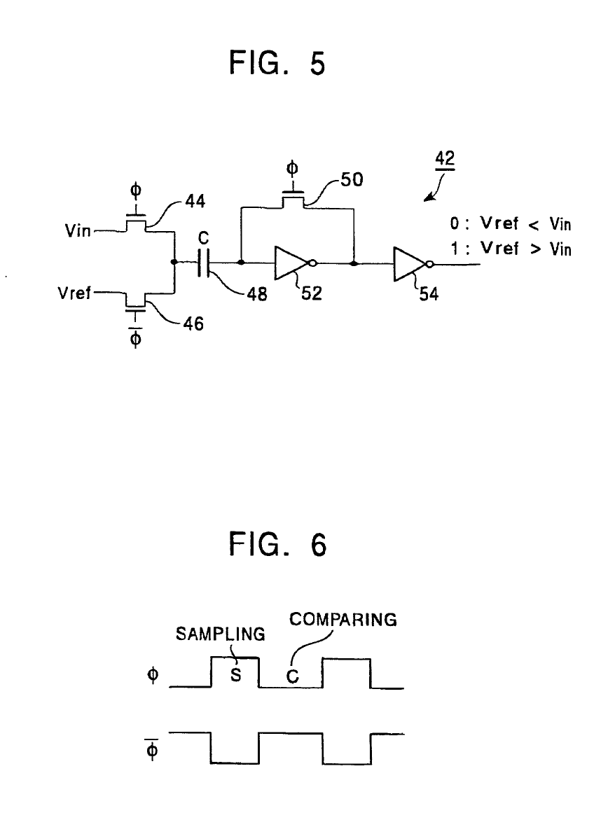

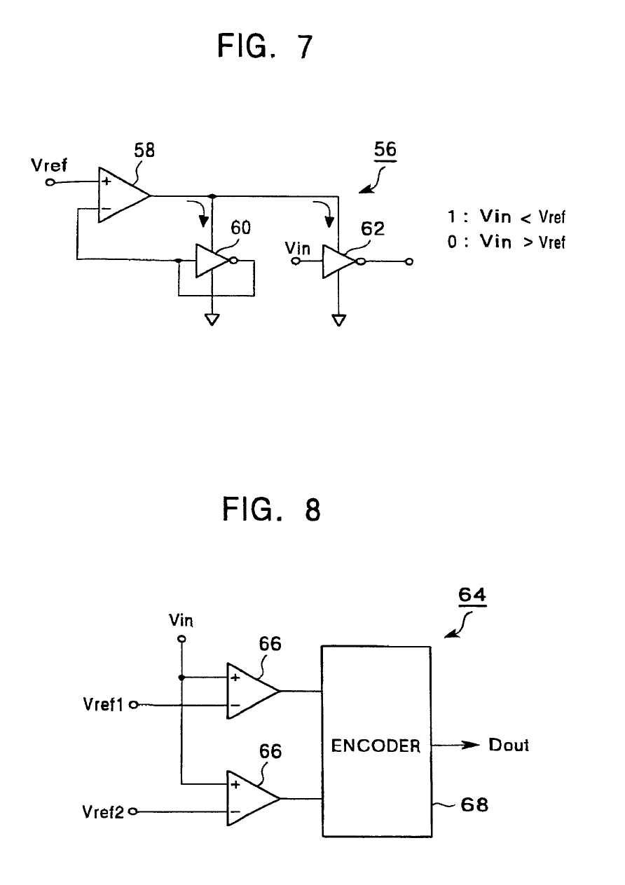

The comparator in accordance with the present invention can be constituted of a N-type comparator 26 as shown in FIG. 3. The N-type comparator 26 shown in FIG. 3 is arranged in a way that NMOSs 28 and 30 are used instead of the PMOSs 20 and 24 in the P-type comparator 10 shown in FIG. 1. These NMOSs 28 and 30 are connected between the ground terminals of the inverters 16 and 22 and the ground, respectively, and the power supply is connected to each of the power supply terminals of the inverters 16 and 22.

In the P-type comparator 10 shown in FIG. 1, the logical threshold voltage of the inverters 16 and 22 are controlled by reducing the power supply voltage supplied to the inverters 16 and 22. Specifically, the logical threshold voltage of the inverters 16 and 22, that is, the reference voltage Vref is arranged to have an upper limit of about a half of the power supply voltage Vdd (i.e., ½ Vdd), with a lower limit of the logical threshold voltage being about the ground voltage GND. The voltage comparison, therefore, can be performed in the range from about the ground voltage GND to about ½ Vdd.

In contrast, in the N-type comparator 26 shown in FIG. 3, the logical threshold voltage of the inverters 16 and 22 is controlled by increasing the ground voltage of the inverters 16 and 22. Specifically, the logical threshold voltage of the inverters 16 and 22, that is, the reference voltage Vref is arranged to have an upper limit of about the power supply voltage Vdd, with a lower limit of the logical threshold voltage being about ½ Vdd. In this case, therefore, the voltage comparison can be performed in the range from about ½ Vdd to about the power supply voltage Vdd.

Next, a preferred embodiment of an A/D converter in accordance with the present invention is described in detail.

FIG. 4 is a schematic diagram showing the structure of an A/D converter 32 in accordance with an embodiment of the present invention.

The A/D converter (hereinafter abbreviated as “ADC”) 32 shown in FIG. 4 is an example of a flash-type ADC including a reference voltage generating circuit 34, a comparator 36 in accordance with the present invention, and an encoder 38. The ADC 32 compares the voltage of an analog input signal Vin with each of a plurality of reference voltages Vref1 to Vref6, and converts the analog input signal Vin into a digital output signal Dout corresponding thereto.

In the ADC 32 in accordance with this embodiment, the reference voltage generating circuit 34 has a ladder resistor that is formed by serially connecting six resistor elements 40 having approximately equal resistances, between the power supply and the ground. The reference voltage generating circuit generates a plurality of reference voltages Vref that are obtained by evenly dividing the voltage between the power supply and the ground. The six reference voltages Vref1 to Vref6 generated by the reference voltage generating circuit 34 are each input to the corresponding first input terminals of the comparator 36.

The comparator 36 includes three N-type comparators 26 and three P-type comparators 10. The comparator 36 compares, in parallel, the voltage of the analog input signal Vin with the six reference voltages Vref1 to Vref6 generated by the reference voltage generating circuit 34. The voltage of the analog input signal Vin is input in common to the second input terminals of the comparator 36. The comparison results output from the comparator 36 are input to the following encoder 38.

This comparator 36 is constructed using the P-type comparators 10 and the N-type comparators 26 in accordance with the present invention. For example, the fundamental structures are illustrated in FIGS. 1 to 3.

Finally, the encoder 38 encodes the comparison results input from the comparator 36, then converts them into the digital output signal Dout corresponding to the analog input signal Vin, and outputs the digital output signal Dout.

In the ADC 32 in accordance with this embodiment, the reference voltage generating circuit 34 generates six reference voltages Vref1 to Vref6 that are obtained by evenly dividing the voltage between the power supply and the ground. The six reference voltages Vref1 to Vref6 are input to the comparator 36, and the voltage of the analog input signal voltage Vin is compared with the six reference voltages Vref1 to Vref6 in parallel. The comparison results are encoded by the encoder 38, and are converted into the digital output signal Dout corresponding to the analog input signal Vin.

Because the ADC 32 in accordance with this embodiment is formed using the comparators 10 and 26 in accordance with the present invention shown in FIGS. 1 and 3, respectively, the ADC 32 can quickly convert the analog input signal Vin into a digital output signal Dout. Moreover, in the ADC 32, because the P-type comparators 10 are disposed on the ground side, and the N-type comparators 26 are disposed on the power supply side, the voltage range of the analog input Vin can be easily extended.

The ADC in accordance with the present invention is not limited to the flash-type shown in FIG. 4, but can be applied to all conventional ones that are formed using comparators. In this preferred embodiment, both the P-type comparator 10 and the N-type comparator 26 are used for the comparator 36, but, depending on the voltage range of the analog input signal Vin, for example, either only the P-type comparator 10 or only the N-type comparator 26 may be used for the comparator 36.

While the present invention has been described with reference to the comparator in accordance with the present invention and the A/D converter using this comparator, it is to be understood that various changes and modifications may be made thereto without departing from the true spirit and scope of the invention.

As is evident from the foregoing, the comparator in accordance with the present invention adjusts the logical threshold voltage of the first and second inverters to become equal to the reference voltage, by using the operational amplifier. That is, the output of the operational amplifier is arranged to be input to the gates of the first and second transistors, and to supply the first and second inverters with currents via the first and second transistors. The A/D converters in accordance with the present invention are formed using the comparators in accordance with the present invention.

Thereby, the comparators in accordance with the present invention are capable of being miniaturized and operated at high speed. Hence, the A/D converters in accordance with the present invention formed using the high-speed comparators in accordance with the present invention are also capable of high speed operation.

What is claimed is:

1. A comparator, comprising:
a dummy section that includes:
a first inverter having an input terminal and an output terminal, an output voltage being output via the output terminal, the input terminal and the output terminal being short-circuited, the first inverter also having at least one of a power supply terminal and a ground terminal;
an operational amplifier having an output terminal, an output being output via the output terminal, a reference voltage being input to the operational amplifier, the output voltage being controlled so that the output voltage of the first inverter and the reference voltage become equal to each other; and
a first transistor that is connected between a power supply and the power supply terminal of the first inverter, or between a ground and the ground terminal of the first inverter, the first transistor having a gate to which the output of the operational amplifier is input; and
a comparison section that includes:
a second inverter, an analog input signal being input to the second inverter, the second inverter having at least one of a power supply terminal and a ground terminal; and
a second transistor that is connected between a power supply and the power supply terminal of the second inverter, or between a ground and the ground terminal of the second inverter, the second transistor having a gate of which the output of the operational amplifier is input.

2. The comparator in accordance with claim 1, wherein the first inverter and the first transistor of the dummy section are formed to have a shape that is similar to the shape of the second inverter and the second transistor of the comparison section, respectively.

3. The comparator in accordance with claim 1, wherein:
the comparison section includes a plurality of stages, and each stage includes the second inverter and the second transistor; and
the analog input signal is input to the second inverter at the first stage, and the output of the second inverter at the previous stage is input to the second inverter at the next stage.

4. The comparator in accordance with claim 1, wherein, in the first and second inverters, the ground terminals or the power supply terminals to which the first and second transistors have not been connected, are connected to the ground or the power supply, respectively.

5. An A/D converter, comprising:
the comparator in accordance with claim 1.

6. The A/D converter in accordance with claim 5, wherein:
the comparator includes at least one N-type comparator and at least one P-type comparator, one of the N-type comparator and the P-type comparator defining one end, and the other of the N-type comparator and the P-type comparator defining another end; and
one end at which the potential is higher than the potential substantially at the midpoint between the power supply and the ground is formed using the N-type comparators, while the other end at which the potential is lower than the potential substantially at the midpoint between the power supply and the ground is formed using the P-type comparators.
